(19) United States
(12) Patent Application Publication
(10) Pub. No.: US 2006/0145139 A1
(43) Pub. Date: Jul. 6, 2006

(54) Organic semiconductor device and its manufacturing method

(75) Inventors: Kenji Nakamura, Tsurugashima-shi (JP); Satoru Ohta, Tsurugashisma-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION, Tokyo (JP)

(21) Appl. No.: 10/526,075

(22) PCT Filed: Aug. 26, 2003
(86) PCT No.: PCT/JP03/10724

§ 371 Date: Oct. 27, 2005

(30) Foreign Application Priority Data
Aug. 30, 2002 (JP) 2002-255279

(51) Int. Cl. H01L 29/08

(52) U.S. Cl. 257/40

(57) ABSTRACT

There are provided an organic semiconductor device and a method of manufacturing the same, which make it possible to easily form a dense polymeric insulating film with high insulating properties as a gate insulating film, without using a vacuum apparatus, and to dispense with the step of patterning the gate insulating film. Gate electrodes 12 are formed on a glass substrate 11. Then, poly(1,4-bis(2-methylstyryl)benzene) (bis-MSB) is dissolved in benzonitrile containing 0.1 mol/l of tetrabutylammonium tetrafluoroborate, whereafter the glass substrate 11 having the gate electrodes 12 formed thereon is soaked in the solution to thereby form dense poly(bis-MSB) films by electrochemical polymerization.

### TECHNICAL FIELD

The present invention relates to an organic semiconductor device and a method of manufacturing the same.

### BACKGROUND ART

In the following, the structure of an organic metal-insulator-semiconductor (MIS) TFT (Thin Film Translator) as an example of an organic semiconductor device will be described with reference to drawings. FIG. 1 is a cross-sectional view schematically showing a bottom contact structure, while FIG. 2 is a cross-sectional view schematically showing a top contact structure.

As shown in FIGS. 1 and 2, organic MIS TFTs 10 and 20 each have a gate electrode 12, a gate insulating film 13, source and drain electrodes 14, and an organic semiconductor film 15, formed on a substrate 11.

As the respective materials of layers forming the organic MIS FET 10 or 20, there are used Ni, Cr, indium tin oxide (ITO), or the like, for the gate electrode 12, a silicon compound, such as SiO₂, SiN, or the like, or a metal oxide or nitride, for the gate insulating film 13, Pd, Au, or the like, for the source and drain electrodes 14, and pentacene or the like, for the organic semiconductor film 15.

When an inorganic material is used for the gate insulating film 13, the radio-frequency (RF) or direct-current (DC) sputtering method, or the chemical vapor deposition (CVD) method is often employed as a method of forming the gate insulating film 13. To form a good quality insulating film uniformly on each gate electrode, another method is sometimes employed in which a gate electrode is formed by a metal, such as Al or Ta, from which an oxide having a high dielectric constant can be obtained, and then anodic oxidation is performed thereon.

Although in the above conventional organic MIS TFT, an inorganic material is used for the gate insulating film 13, a method is being studied which eliminates the use of a vacuum process (i.e. the use of a vacuum apparatus), such as the RF (DC) sputtering method and the CVD method, so as to take advantage of the low cost of organic semiconductor devices. For this purpose, the use of an organic material, such as a polymeric insulating film which can be formed without using a vacuum apparatus, for the gate insulating film 13 is now being considered.

For instance, when a polymeric resin such as polymethyl metacrylate (PMMA) is used for a gate insulating film, a method using a coating method is under consideration. In the following, the method using the coating method for manufacturing an organic semiconductor device will be described with reference to the process diagrams shown in FIGS. 3A-3E.

First, a gate electrode 12 is formed on a substrate 11 as shown in FIG. 3A. Then, a polymeric insulating film is formed from a polymeric resin by coating the substrate and the gate electrode with the polymeric resin as shown in FIG. 3B. The polymeric insulating film formed in the FIG. 3B step is patterned, for example, by etching to form a gate insulating film 13 as shown in FIG. 3C.

Then, the source and drain electrodes 14 are formed as shown in FIG. 3D.

Finally, the organic semiconductor film 15 is formed, for example, by vacuum deposition, as shown in FIG. 3E.

In the method of forming a gate insulating film by using the coating method as shown in FIG. 3B, however, it is difficult to obtain a uniform polymeric film having no pin holes or thickness distribution (i.e. a dense polymeric film having high insulating properties), and further, after formation of a polymeric film, the step (see FIG. 3C) of patterning the polymeric film is necessitated so as to cover the gate electrode with the polymeric film in a desired shape.

The present invention has been made under these circumstances, and an object thereof is to provide an organic semiconductor device and a method of manufacturing the same, which make it possible to easily form a dense polymeric insulating film having high insulating properties, as a gate insulating film, without using a vacuum apparatus, and to dispense with the step of patterning the gate insulating film.

### DISCLOSURE OF INVENTION

To attain the above object, an organic semiconductor device according to the present invention is characterized in that a gate insulating film thereof is a polymeric insulating film formed by an electrochemical polymerization method.

Further, a method of manufacturing an organic semiconductor device, according to the present invention, is characterized by comprising the steps of forming a gate electrode on a substrate, forming a gate insulating film by using a polymeric insulating film formed by an electrochemical polymerization method, forming source and drain electrodes, and forming an organic semiconductor film.

### BRIEF DESCRIPTION OF THE DRAWINGS

FIG. 1 is a cross-sectional view schematically showing the structure of a bottom contact organic MIS TFT;

FIG. 2 is a cross-sectional view schematically showing the structure of a top contact organic MIS TFT;

FIGS. 3A-3E are process diagrams for explaining a method of manufacturing an organic semiconductor device by using the coating method;

FIGS. 4A-4D are process diagrams for explaining an example of a method of manufacturing an organic semiconductor device, according to the present invention; and

FIG. 5 is a cross-sectional view schematically showing an example of a combination of a plurality of organic semiconductor devices.

### DETAILED DESCRIPTION OF THE INVENTION

The present invention will now be described with reference to drawings showing an embodiment thereof.

An organic semiconductor according to the present invention is characterized in that a gate insulating film thereof is a polymeric insulating film formed by electrochemical polymerization.

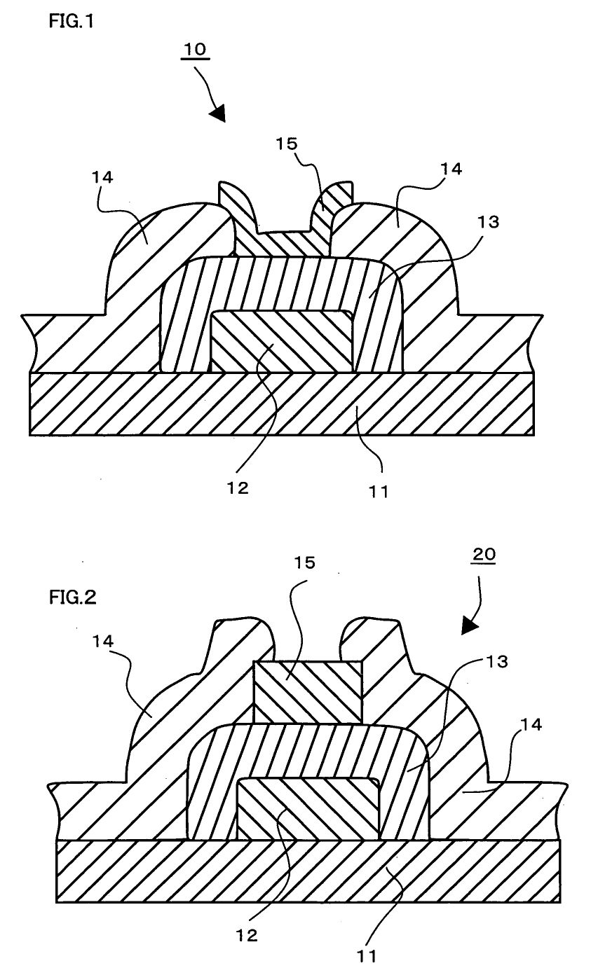

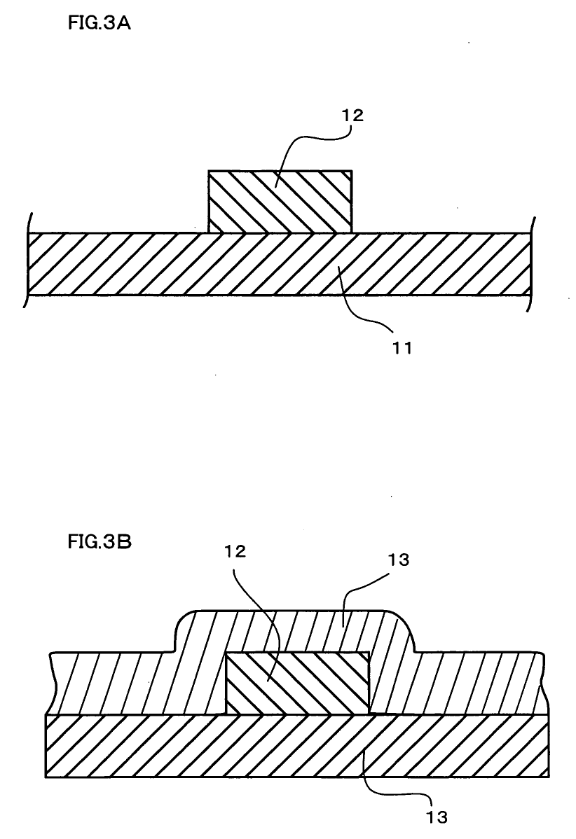

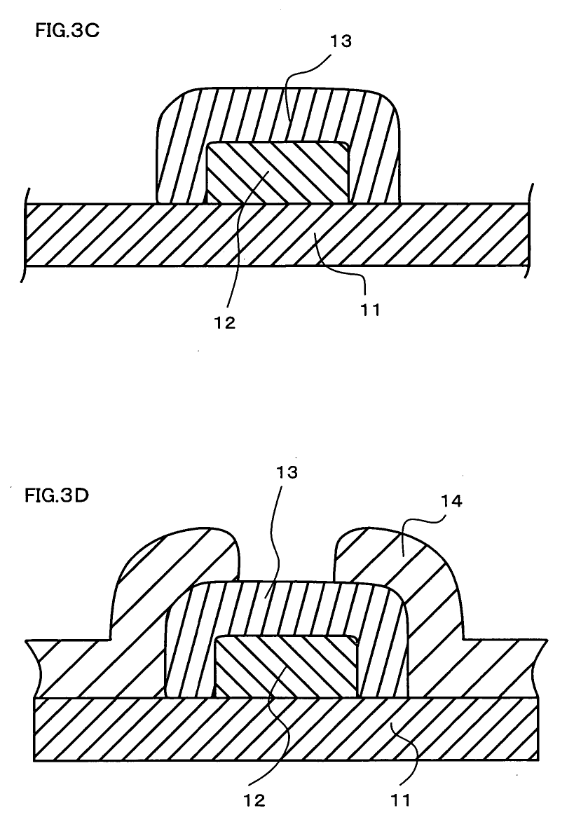

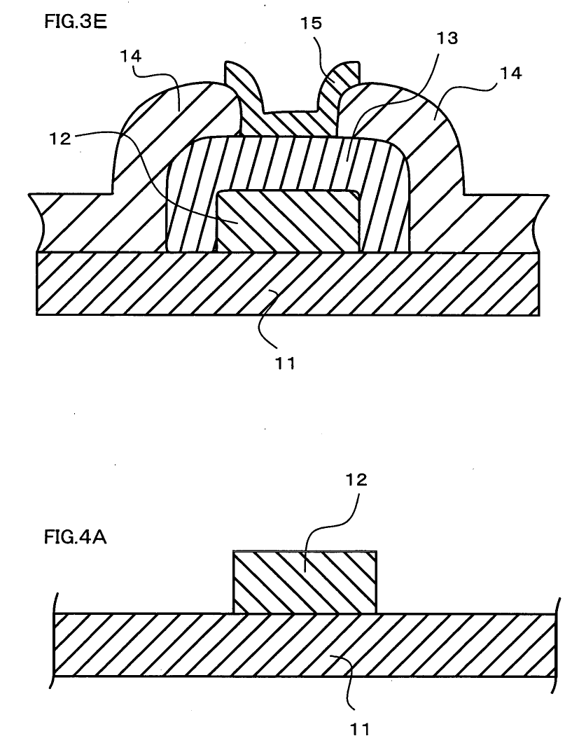

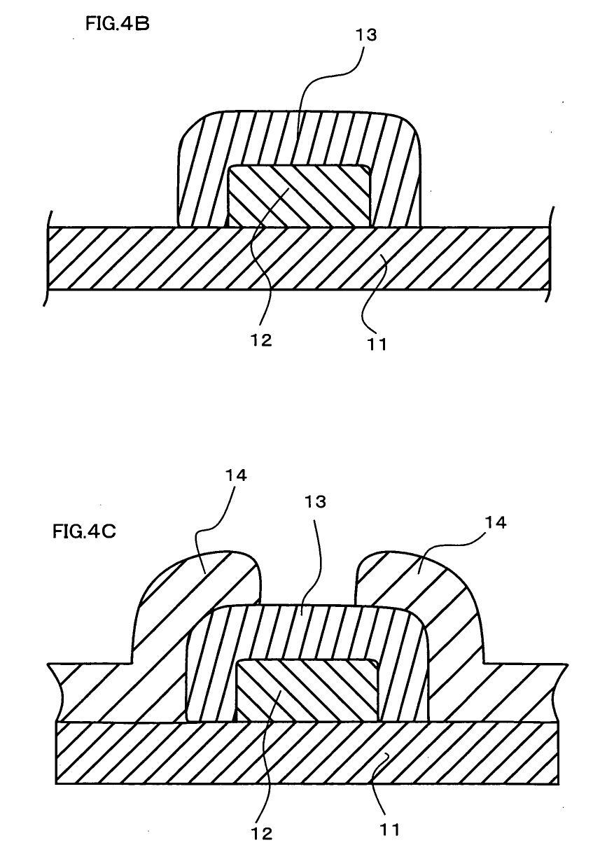

The organic semiconductor of the present invention can be embodied, for example, by an organic MIS TFT which has the structure exemplified in FIG. 1 (bottom contact structure) or FIG. 2 (top contact structure).

As shown in FIGS. 1 and 2, the organic MIS TFTs 10 and 20 each have the gate electrode 12, the gate insulating film 13, the source and drain electrodes 14, and the organic semiconductor film 15, formed on the substrate 11 (e.g. a glass substrate).

For the gate insulating film 13, a material capable of being electropolymerized may be used such as poly(1,4-bis(2-methylstyryl)benzene) (hereinafter abbreviated to bis-MSB), polypyrrole (hereinafter abbreviated to PPy), poly-1-aminopyrrole and the like, without limited to. Such polymer thin films may be formed through an electropolymerization method for example. A solution using a high nucleophilic anion as a supporting electrolyte is prepared. In the solution, while applying an electric field to an electrode, polymers grow from monomers on the electrode as a thin film and at the same time the electrochemical peroxidation makes progress to insulate the thin film, so that the fall of potential occurs in the thickness direction of the resultant polymer thin film. While this polymer insulative film is formed through the peroxidation, conductive portions of the growing film allow to pass electric currents of the peroxidation so that pin holes are automatically repaired, and finally the perfectly contiguous thin film is achieved with a uniform thickness. The thickness of the polymer thin film increases with the lapse of time of polymerization and it may be controlled by the selection of material for the supporting electrolyte in a range of 100-350 nm. In addition, see for PPy e.g., an Article “Design of biosensors based on the insulating electropolymerized polymer: Chemical Sensors Vol. 12, No. 4 (1996)”, and for poly-1-aminopyrrole e.g., an Article “Takayuki KUWAHARA, et. al. Electrochemistry, Vol. 69, No. 8, pp. 598-602, (2001)”.

For the organic semiconductor film 15, there can be used, without limited to, conjugated hydrocarbon polymers, such as polyacetylene, polydiacetylene, polyacene, and polyphenylene vinylene, and derivatives of these conjugated hydrocarbon polymers including oligomers thereof, conjugated heterocyclic polymers, such as polyaniline, polythiophene, polypyrrole, polyfuran, polypyridine, and polythienylene vinylene, and derivatives of these conjugated heterocyclic polymers including oligomers thereof.

More specifically, the organic semiconductor film 15 includes condensed aromatic hydrocarbons, such as tetracene, chrysene, pentacene, pyrene, perylene, and coronene, and derivatives of these condensed aromatic hydrocarbons, and metal complexes of porphyrin and phthalocyanine compounds, such as copper phthalocyanine and lutetium-bis-phthalocyanine.

For the gate electrode 12 or the source and drain electrodes 14, there can be used, without limited to, Rh, Ir, Ni, Pd, Pt, Au, As, Se, Te, Al, Cu, Ag, Mo, W, Mg, Zn, etc. Alternatively, an alloy of any of the above metals may be used.

It should be noted that the films can be formed by using an arbitrary method including a resistance heating vacuum vapor deposition method, a co-vapor deposition method using a plurality of evaporation sources, a sputtering method, a CVD method, and so forth.

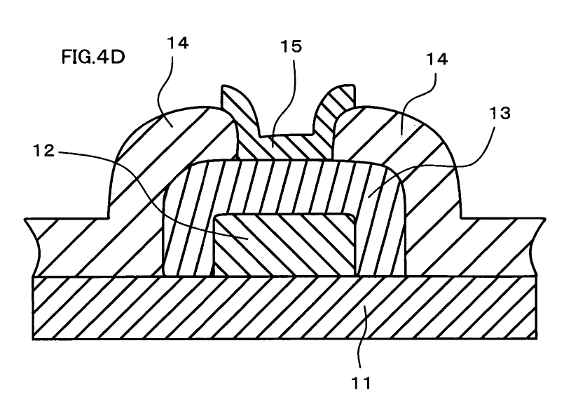

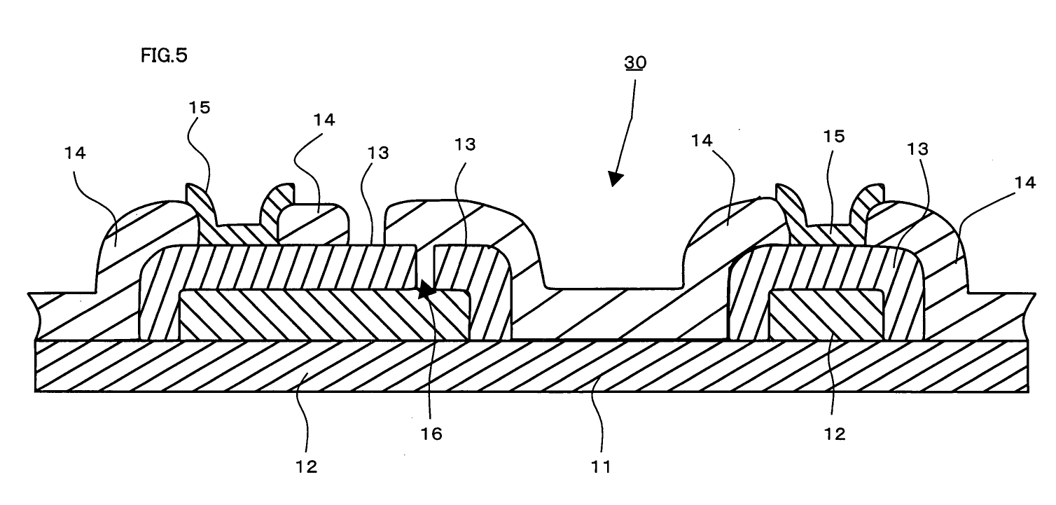

Next, an example of a method of manufacturing an organic semiconductor device according to the present invention will be described with reference to diagrams shown in FIGS. 4A-4D.

First, in a step shown in FIG. 4A, ITO was sputtered on a glass substrate 11 having an excellent flatness, to form ITO films each having a thickness of 1000 Å with a predetermined pattern as gate electrodes 12 (only one of the electrodes is shown in each of FIGS. 4A-4D).

Then, a dense gate insulating film 13 of poly(bis-MSB) having a thickness of 1000 Å was formed only on each gate electrode 12 through the electrochemical polymerization (FIG. 4B). In this step, 1,4-bis(2-methylstyryl)benzene (bis-MSB) was previously dissolved in benzonitrile containing 0.1 mol/l of tetrabutylammonium tetrafluoroborate, whereafter the glass substrate 11 having the gate electrodes 12 formed thereon was soaked in the benzonitrile solution and then electric fields were applied through the gate electrode 12 for the electrochemical polymerization to be performed. In addition to such dipping of the substrate, a spin-coating, spraying and the like are used for the feeding of the solution.

Further the formation of a polymeric insulating film by electrochemical polymerization may be performed by referring to a technique disclosed, for example, in “Japanese Journal of Applied Physics Vol. 30 No. 7A, July 1991, pp. L1192-L1194”.

Then, as shown in FIG. 4C, source and drain electrodes 14 having a thickness of 1000 Å were formed, for example, from Au or Pt by vacuum vapor deposition.

Finally, as shown in FIG. 4D, an organic semiconductor film 15 was formed by forming a film of pentacene having a thickness of 500 Å by vacuum vapor deposition.

In the following, a description will be given of variations of the method of manufacturing an organic semiconductor device.

In the above example, the FIG. 1 organic MIS TFT 10 having the top contact structure was formed, but by reversing the order of the steps of forming the organic semiconductor film 15 and the source and drain electrodes 14, it is possible to form the organic MIS TFT 20 shown in FIG. 2 having the bottom contact structure.

Further, the gate insulating film 13 may be a multi-layered film comprised of an insulating film formed by electrochemical polymerization and an insulating film (inorganic or organic) formed by another method.

Furthermore, the organic semiconductor film 15 may be not a thin film formed of a single material, but a doped thin film or a multi-layered film formed of a plurality of organic semiconductor materials.

Moreover, when a plurality of organic semiconductor devices are used as a combination as shown in FIG. 5, a through hole 16 may be formed in a gate insulating film 13, for example, by etching for electrical connection between source and drain electrodes 14 of one organic MIS TFT and a gate electrode 12 of another organic MIS TFT.

Further, the organic semiconductor according to the embodiment of the present invention may have the gate insulating film 13 formed by a polymerization method (e.g. a thermal polymerization method) other than the electrochemical polymerization method.

As described heretofore, according to the embodiment of the present invention, it is possible to easily form a dense film with high insulating properties without using a vacuum apparatus. Further, the method of the embodiment is much higher in material utilization efficiency than other film-forming methods. Furthermore, since the gate insulating films 13 are selectively formed only on the respective gate electrodes 12, it is not necessary to pattern an insulating film.

In addition, since the gate insulating films 13 are formed uniformly on the respective gate electrodes, it is possible to provide an advantageous effect of sharply reducing the possibility of occurrence of an electrode short circuit at edge portions, which contributes to reduction in manufacturing costs of the organic semiconductor device and improvement in performance of the same.

1. An organic semiconductor device comprising a gate insulating film characterized in that said gate insulating film is a polymeric insulating film formed by a polymerization method.

2. An organic semiconductor device according to claim 1, further comprising a substrate, wherein there are formed on said substrate, a gate electrode, a source electrode, a drain electrode, and an organic semiconductor film.

3. An organic semiconductor device according to claim 2, wherein the organic semiconductor device is an organic MIS TFT.

4. An organic semiconductor device according to any one of claims 1 to 3, wherein said gate insulating film contains poly(1,4-bis(2-methylstyryl)benzene) as a main component.

5. An organic semiconductor device according to any one of claims 1 to 3, wherein said gate insulating film contains polypyrrole as a main component.

6. An organic semiconductor device according to any one of claims 1 to 3, wherein said gate insulating film contains poly-1-aminopyrrole as a main component.

7. A method of manufacturing an organic semiconductor device, characterized by comprising the steps of:
forming a gate electrode on a substrate;
forming a gate insulating film by a polymeric insulating film formed by a polymerization method;
forming source and drain electrodes; and
forming an organic semiconductor film.

8. A method of manufacturing an organic semiconductor device according to claim 7, wherein the organic semiconductor device is an organic MIS TFT.

9. A method of manufacturing an organic semiconductor device according to claim 7 or 8, wherein said step of forming the gate insulating film includes forming the gate insulating film including poly(1,4-bis(2-methylstyryl)benzene) as a main component.

10. A method of manufacturing an organic semiconductor device according to claim 7 or 8, wherein said step of forming the gate insulating film includes forming the gate insulating film including polypyrrole as a main component.

11. A method of manufacturing an organic semiconductor device according to claim 7 or 8, wherein said step of forming the gate insulating film includes forming the gate insulating film including poly-1-aminopyrrole as a main component.

12. A method of manufacturing an organic semiconductor device according to claim 7 or 8, wherein an electric field is applied through the gate electrode in said step of forming the gate insulating film.
